(19) United States
(12) Patent Application Publication
(10) Pub. No.: US 2013/0188299 A1
(43) Pub. Date: Jul. 25, 2013

(54) TOUCH PANEL MODULE

(71) Applicant: MING-WEI KUO, TAIPEI CITY (TW)

(72) Inventor: MING-WEI KUO, TAIPEI CITY (TW)

(73) Assignee: FLYTECH TECHNOLOGY CO., LTD., TAIPEI CITY (TW)

(21) Appl. No.: 13/354,504

(22) Filed: Jan. 20, 2012

(51) Int. Cl. H05K 7/00

(52) U.S. Cl. 361/679.01

(57) ABSTRACT

A touch panel module includes a frame unit and a touch panel unit. The frame unit includes a hollow frame body. The hollow frame body has a receiving space concaved downwardly from the top side thereof, a surrounding positioning portion formed on an inner bottom surface thereof, and an inner ladder structure formed on an inner surrounding peripheral surface thereof. The touch panel unit includes a transparent substrate received in the receiving space and disposed on the surrounding positioning portion by a plurality of adhesive elements and a transparent conductive film received in the receiving space and disposed on the transparent substrate. Therefore, the touch panel unit can naturally aim at the center position inside the hollow frame body due to the design of the inner ladder structure of the hollow frame body.

### BACKGROUND OF THE INVENTION

1. Field of the Invention

The instant disclosure relates to a touch panel module, and more particularly, to a touch panel module for naturally aiming at a center position inside a hollow frame body.

2. Description of Related Art

Touch panels can be produced in a variety of types and sizes without mouse, button or direction key and can be used as input part of a wide variety of electronic devices. With information appliance developing, the touch panels have replaced keyboard and mouse to communicate with the information appliance. The touch panels provide users a friendly interface such that operations of computers or electronic products become simple, straightforward, lively and interesting. Depending on fields of applications, touch panels are applied to portable communication and information products (for example, personal digital assistant (PDA)), financial/commercial system, medical registration system, monitoring system, information guiding system, and computer-aided teaching system, and thereby enhancing convenience of handling for users.

However, the user needs to use extra tool to position the prior touch panel in an external frame.

### SUMMARY OF THE INVENTION

One aspect of the instant disclosure relates to a touch panel module for naturally aiming at a center position inside a hollow frame body.

One of the embodiments of the instant disclosure provides a touch panel module, comprising: a frame unit and a touch panel unit. The frame unit includes a hollow frame body, wherein the hollow frame body has a receiving space concaved downwardly from the top side thereof, a surrounding positioning portion formed on an inner bottom surface thereof and facing the receiving space, and an inner ladder structure formed on an inner surrounding peripheral surface thereof and surrounding the receiving space. The touch panel unit includes a transparent substrate received in the receiving space and disposed on the surrounding positioning portion by a plurality of adhesive elements and a transparent conductive film received in the receiving space and disposed on the transparent substrate, wherein a first shortest distance between an outer surrounding peripheral surface of the transparent substrate and the inner ladder structure is smaller than a second shortest distance between an outer surrounding peripheral surface of the transparent conductive film and the inner ladder structure.

Another one of the embodiments of the instant disclosure provides a touch panel module, comprising: a frame unit and a touch panel unit. The frame unit includes a hollow frame body, wherein the hollow frame body has a receiving space concaved downwardly from the top side thereof, a surrounding positioning portion formed on an inner bottom surface thereof and facing the receiving space, and an inner ladder structure formed on an inner surrounding peripheral surface thereof and surrounding the receiving space. The touch panel unit includes a transparent conductive film received in the receiving space and disposed on the surrounding positioning portion by a plurality of adhesive elements and a transparent substrate received in the receiving space and disposed on the transparent substrate.

Therefore, the touch panel unit can naturally aim at the center position inside the hollow frame body due to the design of the inner ladder structure of the hollow frame body.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1 shows a lateral, cross-sectional, schematic view of the touch panel module according to the first embodiment of the instant disclosure; and

FIG. 2 shows a lateral, cross-sectional, schematic view of the touch panel module according to the second embodiment of the instant disclosure.

### DETAILED DESCRIPTION OF THE PREFERRED EMBODIMENTS

### First Embodiment

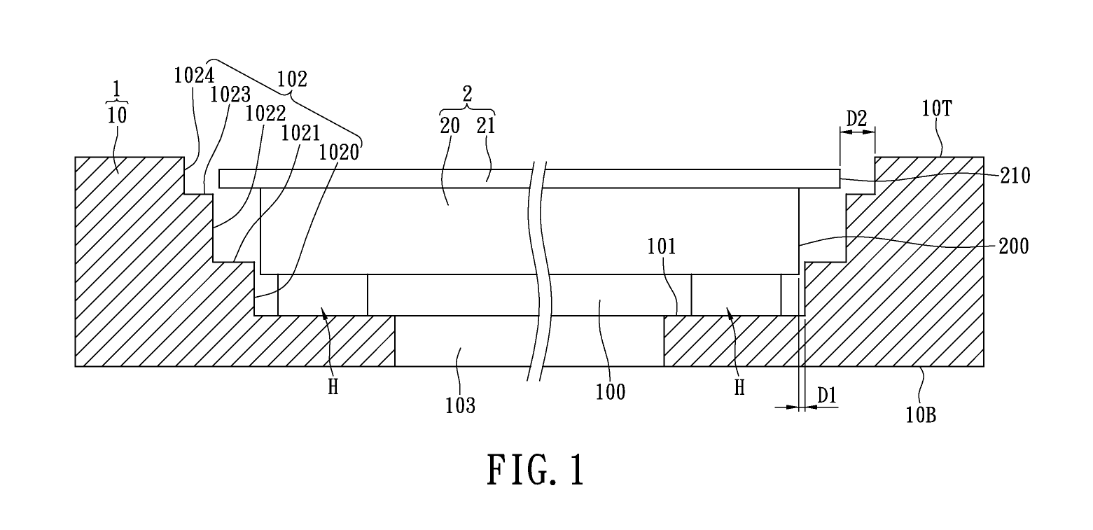

Referring to FIG. 1, where the first embodiment of the instant disclosure a touch panel module for naturally aiming at a center position, comprising: a frame unit 1 and a touch panel unit 2.

The frame unit 1 includes a hollow frame body 10. The hollow frame body 10 has a receiving space 100 concaved downwardly from the top side 10T of the hollow frame body 10, a surrounding positioning portion 101 formed on an inner bottom surface of the hollow frame body 10 and facing the receiving space 100, and an inner ladder structure 102 formed on an inner surrounding peripheral surface of the hollow frame body 10 and surrounding the receiving space 100. In other words, as shown in FIG. 1, the receiving space 100 is formed inside the hollow frame body 10, the surrounding positioning portion 101 is formed on the bottom surface inside of the hollow frame body 10, and the inner ladder structure 102 is formed on the surrounding lateral surface inside the hollow frame body 10.

For example, the hollow frame body 10 has an opening 103 communicated with the receiving space 100, and the surrounding positioning portion 101 on the inner bottom surface is connected with an outer bottom surface (the bottom side 10B) of the hollow frame body 10 through the opening 103. In addition, the inner ladder structure 102 is a surrounding ladder structure, thus the inner ladder structure 102 has a first surrounding lateral surface 1020 extended upwardly from the surrounding positioning portion 101, a first surrounding bottom surface 1021 extended outwardly from the first surrounding lateral surface 1020, a second surrounding lateral surface 1022 extended upwardly from the first surrounding bottom surface 1021, a second surrounding bottom surface 1023 extended outwardly from the second surrounding lateral surface 1022, and a third surrounding lateral surface 1024 extended upwardly from the second surrounding bottom surface 1023 and connected to the top side 10T of the hollow frame body 10. Furthermore, the first surrounding lateral surface 1020 is substantially vertical to the surrounding positioning portion 101, the first surrounding bottom surface 1021 is substantially vertical to the first surrounding lateral surface 1020, the second surrounding lateral surface 1022 is substantially vertical to the first surrounding bottom surface 1021, the second surrounding bottom surface 1023 is substantially vertical to the second surrounding lateral surface 1022, and the third surrounding lateral surface 1024 is substantially vertical to the second surrounding bottom surface 1023 and the top side 10T of the hollow frame body 10. In other words, the first surrounding lateral surface 1020, the first surrounding bottom surface 1021, the second surrounding lateral surface 1022, the second surrounding bottom surface 1023, and the third surrounding lateral surface 1024 can be sequentially connected with each other to form the inner ladder structure 102.

Moreover, the touch panel unit 2 may be a resistive touch panel structure, thus the touch panel unit 2 includes a transparent substrate 20 (such as a transparent glass) received in the receiving space 100 and disposed on the surrounding positioning portion 101 by a plurality of adhesive elements H and a transparent conductive film 21 (such as a ITO film) received in the receiving space 100 and disposed on the transparent substrate 20. In addition, a first shortest distance D1 between an outer surrounding peripheral surface 200 of the transparent substrate 20 and the inner ladder structure 102 is smaller than a second shortest distance D2 between an outer surrounding peripheral surface 210 of the transparent conductive film 21 and the inner ladder structure 102. For example, the first shortest distance D1 is between the outer surrounding peripheral 200 of the transparent substrate 20 and the first surrounding lateral surface 1020 of the inner ladder structure 102, and the second shortest distance D2 is between the outer surrounding peripheral 210 of the transparent conductive film 21 and the third surrounding lateral surface 1024 of the inner ladder structure 102.

Hence, the first shortest distance D1 between the outer surrounding peripheral 200 of the transparent substrate 20 and the first surrounding lateral surface 1020 of the inner ladder structure 102 is very small (such as the first shortest distance D1 is close to 0.1 μm), thus when the touch panel unit 2 is received in the receiving space 100 and disposed on the surrounding positioning portion 101 through the adhesive elements H, the touch panel unit 2 can naturally aim at the center position inside the hollow frame body 10 without using any fixture tool. In addition, when the touch panel unit 2 is received in the receiving space 100 and disposed on the surrounding positioning portion 101 through the adhesive elements H, one or more conductive wires (not shown) electrically connected to the touch panel unit 2 can be shaded by the touch panel unit 2 due to the shape design of the inner ladder structure 102, thus the aspect of the touch panel module can be enhanced.

### Second Embodiment

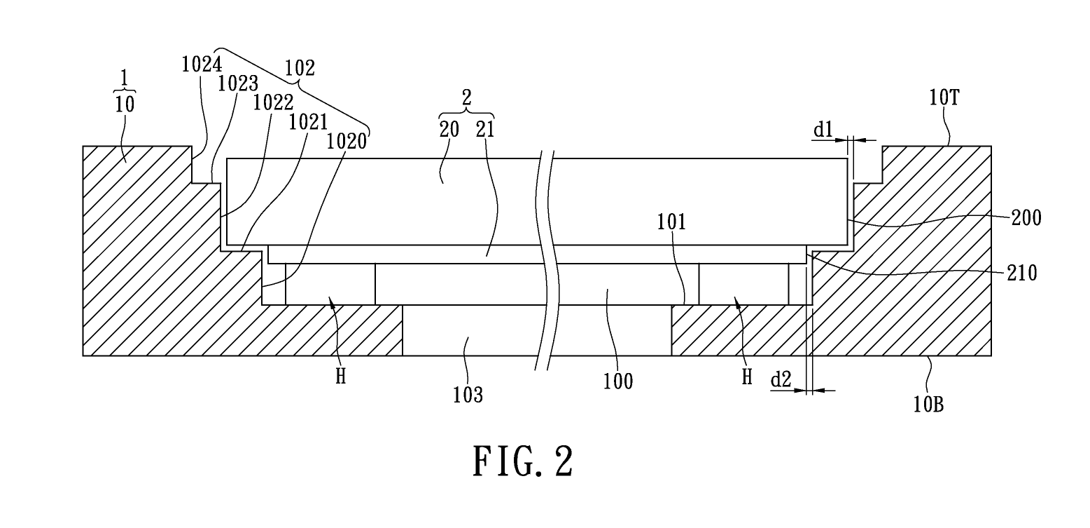

Referring to FIG. 2, where the second embodiment of the instant disclosure a touch panel module for naturally aiming at a center position, comprising: a frame unit 1 and a touch panel unit 2.

The frame unit 1 includes a hollow frame body 10. The hollow frame body 10 has a receiving space 100 concaved downwardly from the top side 10T of the hollow frame body 10, a surrounding positioning portion 101 formed on an inner bottom surface of the hollow frame body 10 and facing the receiving space 100, and an inner ladder structure 102 formed on an inner surrounding peripheral surface of the hollow frame body 10 and surrounding the receiving space 100. In other words, as shown in FIG. 2, the receiving space 100 is formed inside the hollow frame body 10, the surrounding positioning portion 101 is formed on the bottom surface inside of the hollow frame body 10, and the inner ladder structure 102 is formed on the surrounding lateral surface inside the hollow frame body 10.

For example, the hollow frame body 10 has an opening 103 communicated with the receiving space 100, and the surrounding positioning portion 101 on the inner bottom surface is connected with an outer bottom surface (the bottom side 10B) of the hollow frame body 10 through the opening 103. In addition, the inner ladder structure 102 is a surrounding ladder structure, thus the inner ladder structure 102 has a first surrounding lateral surface 1020 extended upwardly from the surrounding positioning portion 101, a first surrounding bottom surface 1021 extended outwardly from the first surrounding lateral surface 1020, a second surrounding lateral surface 1022 extended upwardly from the first surrounding bottom surface 1021, a second surrounding bottom surface 1023 extended outwardly from the second surrounding lateral surface 1022, and a third surrounding lateral surface 1024 extended upwardly from the second surrounding bottom surface 1023 and connected to the top side 10T of the hollow frame body 10. Furthermore, the first surrounding lateral surface 1020 is substantially vertical to the surrounding positioning portion 101, the first surrounding bottom surface 1021 is substantially vertical to the first surrounding lateral surface 1020, the second surrounding lateral surface 1022 is substantially vertical to the first surrounding bottom surface 1021, the second surrounding bottom surface 1023 is substantially vertical to the second surrounding lateral surface 1022, and the third surrounding lateral surface 1024 is substantially vertical to the second surrounding bottom surface 1023 and the top side 10T of the hollow frame body 10. In other words, the first surrounding lateral surface 1020, the first surrounding bottom surface 1021, the second surrounding lateral surface 1022, the second surrounding bottom surface 1023, and the third surrounding lateral surface 1024 can be sequentially connected with each other to form the inner ladder structure 102.

Moreover, the touch panel unit 2 may be a resistive touch panel structure, thus the touch panel unit 2 includes a transparent conductive film 21 (such as a ITO film) received in the receiving space 100 and disposed on the surrounding positioning portion 101 by a plurality of adhesive elements H and a transparent substrate 20 (such as a transparent glass) received in the receiving space 100 and disposed on the transparent substrate 20. In addition, a first shortest distance d1 between an outer surrounding peripheral surface 200 of the transparent substrate 20 and the inner ladder structure 102 is substantially equal to a second shortest distance d2 between an outer surrounding peripheral surface 210 of the transparent conductive film 21 and the inner ladder structure 102. For example, the first shortest distance d1 is between the outer surrounding peripheral 200 of the transparent substrate 20 and the second surrounding lateral surface 1022 of the inner ladder structure 102, and the second shortest distance d2 is between the outer surrounding peripheral 210 of the transparent conductive film 21 and the first surrounding lateral surface 1020 of the inner ladder structure 102.

Hence, the first shortest distance d1 between the outer surrounding peripheral 200 of the transparent substrate 20 and the second surrounding lateral surface 1022 of the inner ladder structure 102 is very small (such as the first shortest distance d1 is close to 0.1 μm), thus when the touch panel unit 2 is received in the receiving space 100 and disposed on the surrounding positioning portion 101 through the adhesive elements H, the touch panel unit 2 can naturally aim at the center position inside the hollow frame body 10 without using any fixture tool. In addition, when the touch panel unit 2 is received in the receiving space 100 and disposed on the surrounding positioning portion 101 through the adhesive elements H, one or more conductive wires (not shown) electrically connected to the touch panel unit 2 can be shaded by the touch panel unit 2 due to the shape design of the inner ladder structure 102, thus the aspect of the touch panel module can be enhanced.

In conclusion, the touch panel unit can naturally aim at the center position inside the hollow frame body due to the design of the inner ladder structure of the hollow frame body.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. A touch panel module, comprising:
a frame unit including a hollow frame body, wherein the hollow frame body has a receiving space concaved downwardly from the top side thereof, a surrounding positioning portion formed on an inner bottom surface thereof and facing the receiving space, and an inner ladder structure formed on an inner surrounding peripheral surface thereof and surrounding the receiving space; and
a touch panel unit including a transparent substrate received in the receiving space and disposed on the surrounding positioning portion by a plurality of adhesive elements and a transparent conductive film received in the receiving space and disposed on the transparent substrate, wherein a first shortest distance between an outer surrounding peripheral surface of the transparent substrate and the inner ladder structure is smaller than a second shortest distance between an outer surrounding peripheral surface of the transparent conductive film and the inner ladder structure.

2. The touch panel module of claim 1, wherein the hollow frame body has an opening communicated with the receiving space, and the inner bottom surface is connected with an outer bottom surface of the hollow frame body through the opening.

3. The touch panel module of claim 1, wherein the inner ladder structure has a first surrounding lateral surface extended upwardly from the surrounding positioning portion, a first surrounding bottom surface extended outwardly from the first surrounding lateral surface, a second surrounding lateral surface extended upwardly from the first surrounding bottom surface, a second surrounding bottom surface extended outwardly from the second surrounding lateral surface, and a third surrounding lateral surface extended upwardly from the second surrounding bottom surface and connected to the top side of the hollow frame body.

4. The touch panel module of claim 3, wherein the first shortest distance is between the outer surrounding peripheral of the transparent substrate and the first surrounding lateral surface of the inner ladder structure, and the second shortest distance is between the outer surrounding peripheral of the transparent conductive film and the third surrounding lateral surface of the inner ladder structure.

5. The touch panel module of claim 3, wherein the first surrounding lateral surface is substantially vertical to the surrounding positioning portion, the first surrounding bottom surface is substantially vertical to the first surrounding lateral surface, the second surrounding lateral surface is substantially vertical to the first surrounding bottom surface, the second surrounding bottom surface is substantially vertical to the second surrounding lateral surface, and the third surrounding lateral surface is substantially vertical to the second surrounding bottom surface and the top side of the hollow frame body.

6. A touch panel module, comprising:
a frame unit including a hollow frame body, wherein the hollow frame body has a receiving space concaved downwardly from the top side thereof, a surrounding positioning portion formed on an inner bottom surface thereof and facing the receiving space, and an inner ladder structure formed on an inner surrounding peripheral surface thereof and surrounding the receiving space; and
a touch panel unit including a transparent conductive film received in the receiving space and disposed on the surrounding positioning portion by a plurality of adhesive elements and a transparent substrate received in the receiving space and disposed on the transparent substrate.

7. The touch panel module of claim 6, wherein the hollow frame body has an opening communicated with the receiving space, and the inner bottom surface is connected with an outer bottom surface of the hollow frame body through the opening.

8. The touch panel module of claim 6, wherein the inner ladder structure has a first surrounding lateral surface extended upwardly from the surrounding positioning portion, a first surrounding bottom surface extended outwardly from the first surrounding lateral surface, a second surrounding lateral surface extended upwardly from the first surrounding bottom surface, a second surrounding bottom surface extended outwardly from the second surrounding lateral surface, and a third surrounding lateral surface extended upwardly from the second surrounding bottom surface and connected to the top side of the hollow frame body.

9. The touch panel module of claim 8, wherein the first shortest distance is between the outer surrounding peripheral of the transparent substrate and the first surrounding lateral surface of the inner ladder structure, and the second shortest distance is between the outer surrounding peripheral of the transparent conductive film and the third surrounding lateral surface of the inner ladder structure.

10. The touch panel module of claim 8, wherein the first surrounding lateral surface is substantially vertical to the surrounding positioning portion, the first surrounding bottom surface is substantially vertical to the first surrounding lateral surface, the second surrounding lateral surface is substantially vertical to the first surrounding bottom surface, the second surrounding bottom surface is substantially vertical to the second surrounding lateral surface, and the third surrounding lateral surface is substantially vertical to the second surrounding bottom surface and the top side of the hollow frame body.
